(19) United States
(12) Patent Application Publication
(10) Pub. No.: US 2013/0023108 A1
(43) Pub. Date: Jan. 24, 2013

(54) METHOD FOR MANUFACTURING SOI SUBSTRATE

(71) Applicants: Kazuya HANAOKA, Fujisawa (JP); Yujiro SAKURADA, Atsugi (JP); Hideki TSUYA, Yokohama (JP); Makoto FURUNO, Atsugi (JP); Miku FUJITA, Isehara (JP)

(72) Inventors: Kazuya HANAOKA, Fujisawa (JP); Yujiro SAKURADA, Atsugi (JP); Hideki TSUYA, Yokohama (JP); Makoto FURUNO, Atsugi (JP); Miku FUJITA, Isehara (JP)

(73) Assignee: SEMICONDUCTOR ENERGY LABORATORY CO., LTD., Atsugi-shi (JP)

(21) Appl. No.: 13/551,677

(22) Filed: Jul. 18, 2012

(30) Foreign Application Priority Data
Jul. 22, 2011 (JP) 2011-161320

(51) Int. Cl. H01L 21/762

(52) U.S. Cl. 438/458; 257/E21.568

(57) ABSTRACT

An insulating layer is formed on a surface of a semiconductor wafer which is to be a bond substrate and an embrittlement region is formed in the semiconductor wafer by irradiation with accelerated ions. Then, a base substrate and the semiconductor wafer are attached to each other. After that, the semiconductor wafer is divided at the embrittlement region by performing heat treatment and an SOI substrate including a semiconductor layer over the base substrate with the insulating layer interposed therebetween is formed. Before the SOI substrate is formed, heat treatment is performed on the semiconductor wafer at a temperature of higher than or equal to 1100° C. under a non-oxidizing atmosphere in which the concentration of impurities is reduced. In this manner, the planarity of the film formed on the semiconductor wafer when heat treatment is performed can be improved.

### BACKGROUND OF THE INVENTION

1. Field of the Invention

The present invention relates to a method for manufacturing a substrate having a silicon on insulator (SOI) structure in which a semiconductor film is provided over the substrate with an insulating film interposed therebetween. Further, the present invention relates to a reprocessing method of a semiconductor wafer which has been used in manufacturing the SOI substrate.

2. Description of the Related Art

A substrate having an SOI structure (hereinafter referred to as an SOI substrate) in which a semiconductor film is provided over the substrate with an insulating film interposed therebetween has attracted attention as a substrate suitable for manufacturing an LSI which has low power consumption and can operate at high speed.

As a method for manufacturing an SOI substrate, a hydrogen ion implantation separation method is known (e.g., see Patent Document 1). The hydrogen ion implantation separation method is a method by which a silicon film is obtained over a base substrate with an insulating film interposed therebetween in the following manner: a silicon wafer (a bond substrate) into which hydrogen ions are implanted is attached to another substrate (a base substrate) with an insulating film interposed between the substrates, and then the silicon wafer (the bond substrate) is separated along an ion implantation region by heat treatment. With the above hydrogen ion implantation separation method, an SOI substrate in which a silicon film is provided over an insulating substrate such as a glass substrate can be manufactured (e.g., see Patent Document 2).

When a hydrogen ion implantation separation method is employed as a method for manufacturing an SOI substrate, a plurality of SOI substrates can be manufactured from a semiconductor wafer which is to be a bond substrate; therefore, there is an advantage that cost for the bond substrate in manufacturing an SOI substrate can be reduced. This is because, when the bond substrate from which a silicon film is separated is subjected to reprocessing treatment, the used bond substrate can be reused for manufacturing another SOI substrate.

However, oxygen is incorporated into the bond substrate because of the manufacturing method; therefore, crystal defects due to oxygen such as oxide precipitate, dislocation, or stacking fault are formed in the vicinity of a surface of the bond substrate which forms the semiconductor film by heat treatment in the manufacturing process of an SOI substrate (typically, heat treatment in a step of forming the thermal oxide film and a step of dividing the bond substrate). Accordingly, the crystal defects in the vicinity of the surface need to be reduced in order to reuse the bond substrate.

Therefore, in order to reuse a bond substrate while the quality of an SOI substrate is maintained, crystal defects due to oxide precipitate in a manufacturing process of the SOI substrate need to be eliminated as reprocessing treatment of the bond substrate. In Patent Document 3, heat treatment at a high temperature of 1150° C. or higher is performed to eliminate such crystal defects.

### REFERENCE

[Patent Document 1] Japanese Published Patent Application No. H5-211128
[Patent Document 2] Japanese Published Patent Application No. 2004-87606
[Patent Document 3] Japanese Published Patent Application No. 2007-251129

### SUMMARY OF THE INVENTION

When heat treatment at high temperature is performed on a plurality of semiconductor wafers with the use of a batch-type vertical diffusion furnace (heating furnace), turbulence of gas may occur near a carrying-in/out chamber of semiconductor wafers or near a gas introduction portion in the furnace. The turbulence of gas causes formation of a film with poor planarity (for example, a natural oxide film) on the semiconductor wafer (particularly, the peripheral portion) or roughness on the surface of the semiconductor wafer.

When the semiconductor wafer on which a film with poor planarity is formed or whose surface is rough as described above is attached to a base substrate as a bond substrate to manufacture an SOI substrate, an attachment defect called an air void is caused at the interface between the bond substrate and the base substrate. An air void causes further defects in manufacturing process of a semiconductor element; therefore, it is not possible to use a semiconductor film in a region where an air void has been caused.

Therefore, in the case where a film with poor planarity is formed on the surface of the semiconductor wafer in heat treatment or roughness of the surface is caused, polishing treatment may be performed in order to improve the planarity of the surface.

However, the semiconductor wafer of a depth of 0.1 μm to 1.5 μm from its surface is removed by polishing treatment, which leads to a reduction in the number of SOI substrates which can be manufactured from one semiconductor wafer. Further, the manufacturing cost is increased by performing polishing treatment.

As a countermeasure against this, a dummy substrate can be provided near the carrying-in/out chamber of semiconductor wafers, the gas introduction portion, or the like. However, the setting of a dummy substrate causes a reduction in the number of semiconductor wafers which can be treated at a time and thus causes a reduction in productivity of an SOI substrate.

As described above, deterioration of the planarity of the surface of the semiconductor wafer caused in heat treatment causes an attachment defect of an SOI substrate or the like, resulting in reducing production efficiency of an SOI substrate.

In view of the above problem, an object of one embodiment of the present invention is to improve the planarity of a surface of a semiconductor wafer. Further, an object of one embodiment of the present invention is to increase productivity of an SOI substrate.

When heat treatment at high temperature is performed on a plurality of semiconductor wafers with the use of a batch-type vertical diffusion furnace (heating furnace), the planarity of the surfaces of the semiconductor wafers is deteriorated near the carrying-in/out chamber of the semiconductor wafers or the gas introduction portion in the furnace. It is possible that this is an adverse effect caused by impurities such as water, nitrogen, and carbon contained in the treatment gas used for heat treatment. Therefore, in one embodiment of the present invention, the planarity of a semiconductor wafer is improved by performing heat treatment on the semiconductor wafer using a treatment gas in which the concentration of impurities is reduced. Further, the transfer speed of the semiconductor wafer is controlled in an unload process in which the semiconductor wafer is taken out from the furnace after heat treatment, which prevents the planarity of the surface of the semiconductor wafer from being deteriorated.

Further, as the treatment gas used for the heat treatment, for example, a rare gas, a hydrogen gas, or a mixed gas of a rare gas and a hydrogen gas can be given. It is preferable that the treatment gas contain as little impurities such as water, nitrogen, and carbon as possible. For example, water contained in the treatment gas is removed to as close to zero as possible so that the concentration of water contained in the treatment gas is higher than or equal to 0.1 ppb and lower than or equal to 300 ppb. This makes it possible to suppress formation of a non-uniform natural oxide film through the reaction between water and the semiconductor wafer in heat treatment. Therefore, the average surface roughness of the surface of the semiconductor wafer can be reduced.

Further, the transfer speed of the semiconductor wafer is higher than or equal to 50 mm/min and lower than or equal to 500 mm/min when the semiconductor wafer is taken out from the furnace after the heat treatment. This makes it possible to suppress formation of a non-uniform natural oxide film through the reaction between a gas other than the treatment gas flowed into the furnace and the semiconductor wafer during the unload process; therefore, the average surface roughness of the surface of the semiconductor wafer can be reduced.

One embodiment of the present invention is a method for manufacturing an SOI substrate including a first step of forming a second semiconductor wafer by performing a first heat treatment on a first semiconductor wafer at a temperature of higher than or equal to 1100° C. and lower than or equal to 1300° C. under a non-oxidizing atmosphere containing water at a concentration of higher than or equal to 0.1 ppb and lower than or equal to 300 ppb; a second step of forming an insulating film on a surface of the second semiconductor wafer and then irradiating the second semiconductor wafer with accelerated ions through the insulating film, to form an embrittlement region in the second semiconductor wafer; a third step of attaching the second semiconductor wafer and a base substrate to each other with the insulating film interposed therebetween; and a fourth step of dividing the second semiconductor wafer at the embrittlement region by performing a second heat treatment, to form a semiconductor film fixed to the base substrate with the insulating film interposed therebetween and a third semiconductor wafer from which the semiconductor film has been separated.

Further, one embodiment of the present invention is a method for manufacturing an SOI substrate including a first step of forming a second semiconductor wafer by performing a first heat treatment on a first semiconductor wafer at a temperature of higher than or equal to 1100° C. and lower than or equal to 1300° C. under a non-oxidizing atmosphere and performing an unload process at a transfer speed of the second semiconductor wafer of higher than or equal to 50 mm/min and lower than or equal to 500 mm/min in taking out the second semiconductor wafer from a furnace after a temperature at the furnace where the first heat treatment has been performed is lowered to higher than or equal to 400° C. and lower than or equal to 700° C.; a second step of forming an insulating film on a surface of the second semiconductor wafer and then irradiating the second semiconductor wafer with accelerated ions through the insulating film, to form an embrittlement region in the second semiconductor wafer; a third step of attaching the second semiconductor wafer and a base substrate to each other with the insulating film interposed therebetween; and a fourth step of dividing the second semiconductor wafer at the embrittlement region by performing a second heat treatment, to form a semiconductor film fixed to the base substrate with the insulating film interposed therebetween and a third semiconductor wafer from which the semiconductor film has been separated.

In the above structure, it is preferable that the non-oxidizing atmosphere contain water at a concentration of higher than or equal to 0.1 ppb and lower than or equal to 300 ppb.

Further, in each of the above structures, the non-oxidizing atmosphere is a rare gas atmosphere, a hydrogen gas atmosphere, or a mixed atmosphere of a rare gas and a hydrogen gas.

Further, one embodiment of the present invention is a method for manufacturing SOI substrates including a first step of forming a second semiconductor wafer by performing a first heat treatment on a first semiconductor wafer at a temperature of higher than or equal to 1100° C. and lower than or equal to 1300° C. under a first non-oxidizing atmosphere and performing an unload process at a transfer speed of the second semiconductor wafer of higher than or equal to 50 mm/min and lower than or equal to 500 mm/min in taking out the second semiconductor wafer from a furnace after a temperature at the furnace where the first heat treatment has been performed is lowered to higher than or equal to 400° C. and lower than or equal to 700° C.; a second step of forming an insulating film on a surface of the second semiconductor wafer and then irradiating the second semiconductor wafer with accelerated ions through the insulating film, to form an embrittlement region in the second semiconductor wafer; a third step of attaching the second semiconductor wafer and a base substrate to each other with the insulating film interposed therebetween; and a fourth step of dividing the second semiconductor wafer at the embrittlement region by performing a second heat treatment, to form a semiconductor film fixed to the base substrate with the insulating film interposed therebetween and a third semiconductor wafer from which the semiconductor film has been separated; a fifth step of planarizing a surface of the third semiconductor wafer, to form a fourth semiconductor wafer; a sixth step of performing the steps from the second step to the fifth step at least once by using the fourth semiconductor wafer as the second semiconductor wafer; a seventh step of forming a fifth semiconductor wafer by performing a third heat treatment on the fourth semiconductor wafer at a temperature of higher than or equal to 1100° C. and lower than or equal to 1300° C. under a second non-oxidizing atmosphere and performing an unload process at a transfer speed of the fifth semiconductor wafer of higher than or equal to 50 mm/min and lower than or equal to 500 mm/min in taking out the fifth semiconductor wafer from the furnace after a temperature at the furnace where the third heat treatment has been performed is lowered to higher than or equal to 400° C. and lower than or equal to 700° C.; and an eighth step of performing the steps from the second step to the fifth step at least once by using the fifth semiconductor wafer as the second semiconductor wafer, in which the steps from the first step to the fifth step are sequentially performed once and then the steps from the sixth step to the eighth step are repeatedly performed.

In the above structure, the first non-oxidizing atmosphere and the second non-oxidizing atmosphere contain water at a concentration of higher than or equal to 0.1 ppb and lower than or equal to 300 ppb.

Further, in each of the above structures, the first non-oxidizing atmosphere is a rare gas atmosphere, a hydrogen gas atmosphere, or a mixed atmosphere of a rare gas and a hydrogen gas. Furthermore, the second non-oxidizing atmosphere is a rare gas atmosphere, a hydrogen gas atmosphere, or a mixed atmosphere of a rare gas and a hydrogen gas.

In this example, the average surface roughness (Rₐ) is obtained by expanding into three dimensions arithmetic mean surface roughness Rₐ which is defined by JIS B 0601:2001 (ISO 4287:1997) so as to be able to apply Rₐ to a measurement surface. Rₐ can be expressed as an “average value of the absolute values of deviations from a reference surface to a specific surface” and is defined by the following formula (1).

$$\begin{matrix}[ FORMULA 1 ] & \\ {R}_{a} = \frac{1}{{S}_{0}} {\int }_{{Y}_{1}}^{{Y}_{2}} {\int }_{{X}_{1}}^{{X}_{2}} \vert F ( X , Y ) - {Z}_{0} \vert d X d Y & ( 1 )\end{matrix}$$

The measurement surface is a surface which is shown by the all measurement data, and is expressed by the following formula (2).

[FORMULA 2]

Z=F(X,Y) (2)

The specific surface is a surface which is an object of roughness measurement, and is a rectangular region which is surrounded by four points represented by the coordinates (X₁, Y₁), (X₁, Y₂), (X₂, Y₁), and (X₂, Y₂). The area of the specific surface when the specific surface is flat ideally is denoted by S₀. Note that S₀ is expressed by the following formula (3).

[FORMULA 3]

S₀=(X₂−X₁)·(Y₂−Y₁) (3)

The reference surface is a plane surface represented by Z=Z₀ when Z₀ is the average value of height of the specific surface. The reference surface is parallel to the XY plane. Note that Z₀ is expressed by the following formula (4).

$$\begin{matrix}[ FORMULA 4 ] & \\ {Z}_{0} = \frac{1}{{S}_{0}} {\int }_{{Y}_{1}}^{{Y}_{2}} {\int }_{{X}_{1}}^{{X}_{2}} F ( X , Y ) d X d Y & ( 4 )\end{matrix}$$

According to one embodiment of the present invention, the planarity of the surface of the semiconductor wafer can be improved. This makes it possible to suppress an attachment defect between the semiconductor wafer and the base substrate in manufacturing an SOI substrate. Further, the number of SOI substrates which are manufactured from one semiconductor wafer can be increased.

Furthermore, according to one embodiment of the present invention, the number of substrates which can be treated at a time can be increased and thus productivity of an SOI substrate can be improved.

### BRIEF DESCRIPTION OF THE DRAWINGS

FIG. 1 is a flow chart illustrating an example of a method for manufacturing SOI substrates according to one embodiment of the present invention.

FIG. 2 is a cross-sectional view of a vertical diffusion furnace.

FIGS. 3A to 3I are cross-sectional views illustrating an example of a method for manufacturing an SOI substrate according to one embodiment of the present invention.

FIG. 4A shows an observation image of Wafer A1 obtained with AFM and FIG. 4B is a graph showing the average surface roughness (Rₐ) of Wafer A1 at each point.

FIG. 5A shows an observation image of Wafer A2 obtained with AFM and FIG. 5B is a graph showing the average surface roughness (Rₐ) of Wafer A2 at each point.

FIG. 6A shows an observation image of Wafer B1 obtained with AFM and FIG. 6B is a graph showing the average surface roughness (Rₐ) of Wafer B1 at each point.

FIG. 7A shows an observation image of Wafer C1 obtained with AFM and FIG. 7B is a graph showing the average surface roughness (Rₐ) of Wafer C1 at each point.

FIG. 8A shows an observation image of Wafer C2 obtained with AFM and FIG. 8B is a graph showing the average surface roughness (Rₐ) of Wafer C2 at each point.

### DETAILED DESCRIPTION OF THE INVENTION

Embodiments are described below in detail using the drawings. Note that the present invention is not limited to the description of the embodiments, and it is apparent to those skilled in the art that modes and details can be modified in various ways without departing from the spirit of the present invention disclosed in this specification and the like. A structure of the different embodiment can be implemented by combination appropriately. On the description of the invention with reference to the drawings, a reference numeral indicating the same part is used in common throughout different drawings, and the repeated description is omitted.

In this embodiment, a method for forming an SOI substrate will be described. In the method for manufacturing an SOI substrate of this embodiment, first, heat treatment is performed on a semiconductor wafer which is to be a bond substrate at a temperature of higher than or equal to 1100° C. and lower than or equal to 1300° C. under a non-oxidizing atmosphere. After that, an insulating film and an embrittlement region are provided for the semiconductor wafer. Then, the semiconductor wafer and a base substrate are attached to each other with the insulating film interposed therebetween and the semiconductor wafer is divided at the embrittlement region, so that an SOI substrate including a semiconductor film, the insulating film, and the base substrate is formed.

Further, reprocessing treatment for reusing the semiconductor wafer after the division is also described in this embodiment. In this embodiment, the reprocessing treatment includes at least a step for planarizing a surface from which the semiconductor film is separated. In addition, every time the semiconductor wafer is used N times (N is an integer of 2 or more) to manufacture SOI substrates, the semiconductor wafer is subjected to heat treatment at a temperature of higher than or equal to 1100° C. and lower than or equal to 1300° C. in addition to planarization treatment as the reprocessing treatment. That is, heat treatment at high temperature is performed once per N times in the reprocessing treatment, not every time the semiconductor wafer is reused.

### <Flow Chart of Method for Manufacturing SOI Substrates>

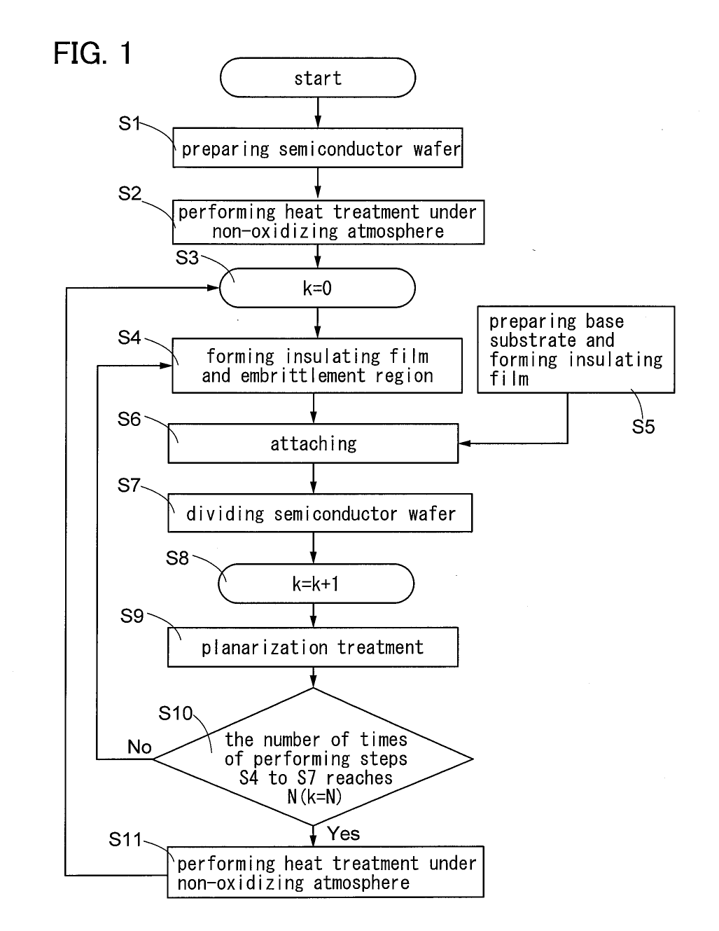

FIG. 1 is a flow chart illustrating an example of a method for manufacturing SOI substrates of this embodiment and including a reprocessing treatment step in the case where a semiconductor wafer is repeatedly used as a bond substrate.

First, a bulk semiconductor wafer which is to be a bond substrate is prepared as illustrated in Step S1. As the semiconductor wafer, a semiconductor wafer formed using an element belonging to Group 14 of the periodic table, such as a silicon wafer, a germanium wafer, or a silicon germanium wafer can be used. In order to form a high-performance integrated circuit using an SOI substrate, a single crystal semiconductor wafer is preferably used. Alternatively, a floating zone (FZ) semiconductor wafer obtained by slicing an ingot formed by an FZ method or a Czochralski (CZ) semiconductor wafer obtained by slicing an ingot formed by a CZ method can be used. The CZ semiconductor wafer includes a magnetic field applied CZ (MCZ) semiconductor wafer obtained by slicing an ingot formed by an MCZ method. An MCZ method, which is one kind of CZ methods, is a method in which a magnetic field is applied to a melt of a semiconductor to suppress the convection of the melt so that crystal growth of the semiconductor is controlled.

Before an SOI substrate manufacturing process (Steps S4 to S7) is performed on the semiconductor wafer, heat treatment is performed on the semiconductor wafer under a non-oxidizing atmosphere (Step S2). This heat treatment is performed for outward diffusion of oxygen in the semiconductor wafer and formation of a zero defect layer (a DZ, a denuded zone) in the vicinity of the surface. Further, through this heat treatment, oxygen supersaturated inside the semiconductor wafer is separated out as an oxide, and minute crystal defects are formed. Such minute defects due to oxide precipitate are called bulk micro defects (BMDs). BMDs formed inside the semiconductor wafer can function as gettering sinks for gettering metal elements in the manufacturing process of an SOI substrate.

Note that in this specification, a DZ means a region without BMDs, not a completely zero defect layer.

This heat treatment can be performed in a batch-type heating furnace (including a diffusion furnace or the like). Batch-type heating furnaces can process a plurality of substrates at a time and have high temperature controllability.

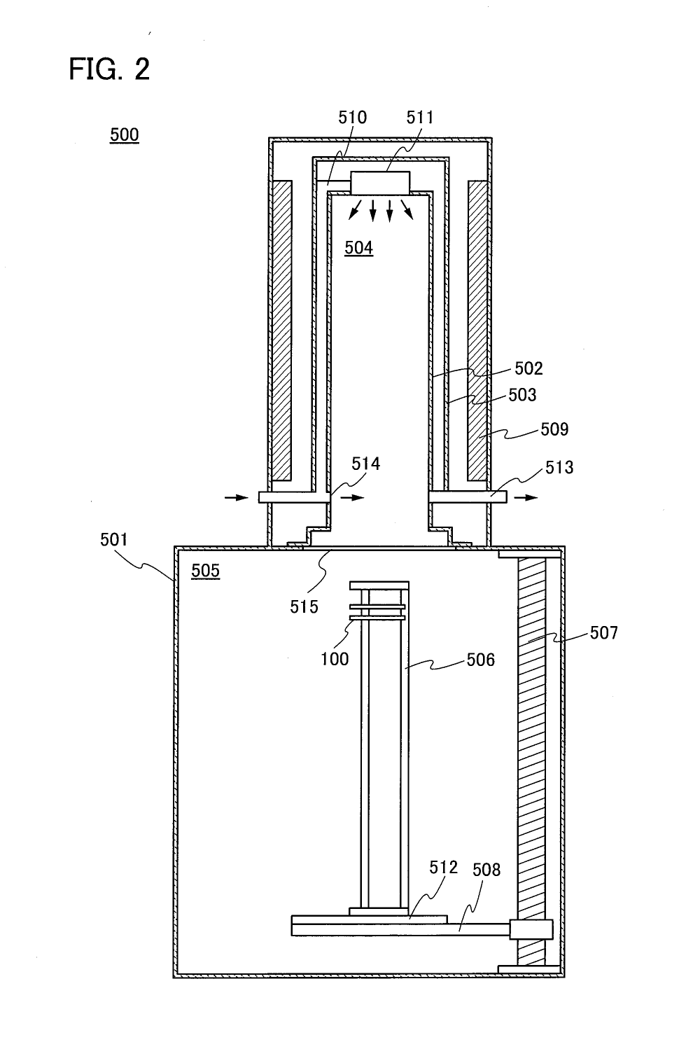

FIG. 2 illustrates a schematic cross-sectional view of a vertical heating furnace. A vertical heating furnace 500 is provided with, for example, a treatment chamber 504 (also referred to as a furnace) which includes an inner pipe 502 and an outer pipe 503, and a housing 501 which includes a boat carrying-in/out chamber 505. Further, an opening and closing apparatus 515 for opening and closing the treatment chamber 504 is provided between the treatment chamber 504 and the boat carrying-in/out chamber 505.

A boat elevator 508 including a feed screw spindle 507 driven by a motor is provided in the boat carrying-in/out chamber 505. A seal cap 512 is provided over the boat elevator 508 and a boat 506 is provided over the seal cap 512. A plurality of semiconductor wafers 100 can be set in the boat 506.

A heater 509 is provided outside the treatment chamber 504 to surround the treatment chamber 504 and is supported by the housing 501. The heater 509 can control the temperature of the treatment chamber 504 to a predetermined temperature by heating.

Further, a gas introduction pipe 510 is connected to the treatment chamber 504 and a predetermined treatment gas is supplied to the treatment chamber 504 from gas inlets 511 and 514. Furthermore, a gas exhaust pipe 513 is connected to the treatment chamber 504 and a gas pressure in the treatment chamber 504 can be set to a predetermined pressure.

A heat treatment method of a semiconductor wafer in this embodiment will be described. Note that arrows in FIG. 2 represent the direction of movement of the treatment gas.

First, the plurality of semiconductor wafers 100 is transferred to and set in the boat 506. After that, the treatment chamber 504 is opened by the opening and closing apparatus 515 and the boat elevator 508 is raised, so that the boat 506 provided with the plurality of semiconductor wafers 100 is put into the treatment chamber 504. Thus, the treatment chamber 504 is sealed with the seal cap 512.

Here, when the semiconductor wafers are put from the boat carrying-in/out chamber 505 into the treatment chamber 504, the transfer speed of the boat 506 (the semiconductor wafers 100) is preferably higher than or equal to 50 mm/min and lower than or equal to 500 mm/min. The boat 506 is moved from the boat carrying-in/out chamber 505 to the treatment chamber 504 at the above transfer speed, whereby impurities can be prevented from being attached to the semiconductor wafers 100. When the semiconductor wafers 100 are set in the treatment chamber 504, the treatment chamber 504 may have a non-oxidization atmosphere by introducing a rare gas such as argon to the treatment chamber 504. Alternatively, nitrogen may be introduced instead of a rare gas. In the case where nitrogen is introduced, it is preferable that the concentration of nitrogen be reduced to lower than or equal to 300 ppb in the treatment chamber 504 before the heat treatment is performed.

Next, a predetermined treatment gas is supplied to the treatment chamber 504 from the gas introduction pipe 510 and the gas inlet 514 so that a predetermined gas pressure and temperature are obtained. Specifically, the heat treatment temperature in Step S2 is a temperature at which outward diffusion of oxygen occurs, and is preferably higher than or equal to 1100° C., more preferably higher than or equal to 1200° C. The upper limit of the heat treatment temperature is a temperature at which the semiconductor wafer does not change its shape. In consideration of the melting point of silicon 1415° C., the heat treatment temperature is preferably higher than or equal to 1100° C. and lower than or equal to 1300° C., more preferably higher than or equal to 1200° C. and lower than or equal to 1300° C.

The treatment time in the heating furnace (time at which the temperature of the object to be processed is maintained at a process temperature) is at least 1 hour. This is because when the heating time is short, outward diffusion of oxygen is not sufficiently performed and the oxygen concentration in the vicinity of the surface of the semiconductor wafer becomes high. In consideration of effects of the heat treatment and productivity, the process time is preferably greater than or equal to 1 hour and less than or equal to 24 hours, more preferably greater than or equal to 6 hours and less than or equal to 20 hours.

Further, as the treatment gas, a rare gas such as helium or argon, hydrogen, or a mixed gas of a rare gas and hydrogen can be used. In terms of cost, safety, and controllability of the atmosphere, an argon gas is preferably used as the treatment gas.

With the use of the above treatment gas, the treatment chamber 504 has a non-oxidizing atmosphere. The flow rate of the above gas is greater than or equal to 5 SLM and less than or equal to 20 SLM (greater than or equal to 8.35 atm·cm³/s and less than or equal to 3.34×10² atm·cm³/s). Note that SLM (standard liter/min) is flow rate (liter) per minute at 1 atm and at 0° C.

Further, it is preferable that an impurity such as nitrogen, carbon, or water be not contained in the hydrogen and/or the rare gas. For example, the purity of the hydrogen and/or the rare gas introduced into the heating furnace is set to higher than or equal to 7N (99.99999%), preferably higher than or equal to 8N (99.999999%), more preferably higher than or equal to 9N (99.9999999%) (i.e., the impurity concentration is lower than or equal to 100 ppb, preferably lower than or equal to 10 ppb, more preferably lower than 1 ppb). Further, the concentration of water contained in the non-oxidizing atmosphere is higher than or equal to 0.01 ppb and lower than or equal to 1%, preferably higher than or equal to 0.1 ppb and lower than or equal to 300 ppb. A reduction in the concentration of impurities contained in the non-oxidizing atmosphere makes it possible to suppress formation of a non-uniform natural oxide film through the reaction between impurities and the semiconductor wafer in heat treatment. Therefore, the average surface roughness of the surface of the semiconductor wafer can be reduced.

Oxygen may be contained at a concentration of higher than or equal to 0.1 ppb and lower than or equal to 1% in the non-oxidizing atmosphere. By performing heat treatment on the semiconductor wafer in such a non-oxidizing atmosphere, a uniform oxide film can be formed on the semiconductor wafer. The oxide film (the natural oxide film) formed on the semiconductor wafer preferably has a thickness greater than or equal to several nanometers and less than or equal to 40 nm. In the case where the natural oxide film has a thickness less than several nanometers, the surface of the semiconductor wafer may be roughened in the heat treatment, and in the case of a thickness greater than 40 nm, outward diffusion of oxygen in the semiconductor wafer is not efficiently performed. For example, when heat treatment is performed at 1200° C. for 16 hours under an argon atmosphere containing water at 300 ppb, a natural oxide film having a thickness of approximately 1 nm to 2 nm is formed on the surface of the semiconductor wafer. Furthermore, when heat treatment is performed at 1200° C. for 2 hours under an argon atmosphere containing oxygen gas at 1%, an oxide film having a thickness of approximately 40 nm is formed on the surface of the semiconductor wafer. As long as the thickness of the oxide film (the natural oxide film) is in the above range, outward diffusion of oxygen in the semiconductor wafer can be promoted.

After the heat treatment is performed, the temperature at the treatment chamber 504 in the heating furnace is lowered to higher than or equal to 400° C. and lower than or equal to 700° C. The temperature at the treatment chamber 504 in the heating furnace may be lowered at a rate of higher than or equal to 1.5° C./min and lower than or equal to 3.0° C./min.

Next, an unload process is performed, in which the semiconductor wafers are taken out from the treatment chamber 504 where heat treatment has been performed. In the unload process, the boat 506 provided with the plurality of semiconductor wafers is taken out from the treatment chamber 504 to the boat carrying-in/out chamber 505 by lowering the boat elevator 508. Further, when the unload process is started, that is, when the boat 506 is taken out from the treatment chamber 504, the temperature of the treatment chamber 504 is set to higher than or equal to 400° C. and less than or equal to 800° C. This is because in the case where the temperature at the treatment chamber 504 is less than 400° C. in taking out the semiconductor wafers from the treatment chamber 504, it takes much time to descend the temperature and thus a reduction in productivity is caused. In addition, in the case where the temperature is higher than 800° C., the planarity of the surface of the oxide film which is formed on the surface of the semiconductor wafer is deteriorated. Further, in the case where the temperature is higher than 800° C., the boat carrying-in/out chamber 505 may be influenced by radiant heat.

Further, in the unload process, the transfer speed of the boat 506 (the semiconductor wafers 100) is preferably higher than or equal to 50 mm/min and lower than or equal to 500 mm/min in taking out the semiconductor wafers 100 from the treatment chamber 504 to the boat carrying-in/out chamber 505. In the case where the transfer speed is lower than 50 mm/min, a non-uniform oxide film is formed on a surface of the semiconductor wafer 100 due to a gas containing impurities flowed into from the boat carrying-in/out chamber 505 to the treatment chamber 504 (a gas other than gas used for the treatment) while the semiconductor wafers are moved from the treatment chamber 504 to the boat carrying-in/out chamber 505 and thus the planarity of the semiconductor wafer 100 is deteriorated. In particular, the semiconductor wafers 100 set in an upper part of the boat are kept in a gas containing impurities for a long time; therefore, the surface of the oxide film is extremely roughened. Further, in the case where the transfer speed is higher than 500 mm/min, a crystal defect such as a slip may be caused. Therefore, when the transfer speed is higher than or equal to 50 mm/min and lower than or equal to 500 mm/min, the semiconductor wafer 100 on which the oxide film having a favorably planar surface is provided can be obtained.

Further, the unload process in which the semiconductor wafers 100 are taken out may be performed while the treatment gas supplied to the treatment chamber 504 in the heat treatment process is supplied to the treatment chamber where heat treatment has been performed on the semiconductor wafers 100. For example, the unload process is performed while the treatment gas is supplied from each of the upper gas inlet 511 and the lower gas inlet 514, which leads to a reduction in the concentration of a gas other than the treatment gas contained in the atmosphere in the treatment chamber 504. Further, supply of the treatment gas from the lower gas inlet 514 makes it possible to suppress the entry of a gas other than the treatment gas from the boat carrying-in/out chamber 505 into the treatment chamber 504.

In such a manner, by performing heat treatment on the semiconductor wafer 100, the average surface roughness (Rₐ) of the oxide film which is formed on the surface of the semiconductor wafer 100 can be less than or equal to 0.4 nm, preferably less than or equal to 0.2 nm, more preferably less than 0.1 nm. Therefore, when the semiconductor wafer and a base substrate are attached to each other, an attachment defect such as an air void can be reduced. Further, it is not necessary to perform polishing treatment on the semiconductor wafer after the heat treatment; therefore, simplification of the process can be achieved. It is not also necessary to remove the semiconductor wafer 100 partly by polishing treatment; therefore, the number of SOI substrates which can be manufactured at one heat treatment can be increased.

Further, the planarity of the semiconductor wafer 100 can be improved regardless of a position of the semiconductor wafer 100 in the boat 506, so that a dummy substrate is not necessary. This makes it possible to increase the number of semiconductor wafers which can be treated at a time and thus to improve productivity in a manufacturing process of an SOI substrate.

Next, the first manufacturing process of an SOI substrate is conducted. Steps S4 to S7 are the manufacturing process of an SOI substrate. In the flow chart of FIG. 1, k represents the number of times the manufacturing process of an SOI substrate is performed using the semiconductor wafer which is prepared in Steps S1 and S2; thus, in Step S4 after Step S2 is performed, k=0 (Step S3). In FIG. 1, heat treatment is performed on the semiconductor wafer as reprocessing treatment once per N times (N is an integer of 2 or more) the manufacturing processes of an SOI substrate are performed, and crystal defects in the vicinity of the surface of the semiconductor wafer are reduced.

Step S4 is treatment for the semiconductor wafer and a step of providing an insulating film and an embrittlement region for the semiconductor wafer.

The insulating film is formed at least on a surface of the semiconductor wafer to be attached to a base substrate. This insulating film may be a single layer or a plurality of layers. As a layer which forms the insulating film, for example, a silicon oxide film, a silicon nitride film, a silicon oxynitride film, a silicon nitride oxide film, or the like can be formed. Further, the insulating film can be formed by a chemical vapor deposition (CVD) method, a sputtering method, or an atomic layer epitaxy (ALE) method. Furthermore, by oxidation treatment and/or nitridation treatment on the semiconductor wafer, the layer which forms the insulating film can be formed.

The embrittlement region can be formed by irradiating the semiconductor wafer with ions having kinetic energy. An ion implantation apparatus or an ion doping apparatus can be used for the formation of the embrittlement region.

There is no limitation on the order of the formation of the insulating film and the embrittlement region in Step S4. Note that in order to prevent the contamination by metal in forming the embrittlement region, ion irradiation is preferably performed after at least one layer of an insulating film is formed. An embrittlement region may be formed in such a manner, for example: the semiconductor wafer is subjected to thermal oxidation in an atmosphere containing HCl and oxygen to form a silicon oxide film over the semiconductor wafer, and then the semiconductor wafer is irradiated with hydrogen ions through the silicon oxide film. After the embrittlement region is formed, a second layer of the insulating film such as a silicon oxynitride film may be formed over the silicon oxide film by a CVD method or the like.

As illustrated in Step S5, a base substrate is prepared. A substrate formed of an insulator or a bulk semiconductor wafer can be used for the base substrate. As the substrate formed of an insulator, a glass substrate, a quartz substrate, a ceramic substrate, a sapphire substrate, or the like is given. Note that as a material of the glass substrate, aluminosilicate glass, aluminoborosilicate glass, barium borosilicate glass, or the like is given. As the semiconductor wafer which is applied to the base substrate, for example, a semiconductor wafer formed using an element belonging to Group 14 of the periodic table, such as a silicon wafer, a germanium substrate, or a silicon germanium substrate can be used. Needless to say, a substrate which can withstand a process temperature of the manufacturing process of an SOI substrate is selected for the base substrate.

Note that in this specification, an oxynitride is a substance with a composition in which the number of oxygen atoms is more than the number of nitrogen atoms, and a nitride oxide is a substance with a composition in which the number of nitrogen atoms is more than the number of oxygen atoms.

In Step S5, an insulating film having a single layer or a plurality of layers is formed over the base substrate as necessary. As a layer which forms the insulating film, for example, a silicon oxide film, a silicon nitride film, a silicon oxynitride film, a silicon nitride oxide film, or the like can be formed. Further, the insulating film can be formed by a chemical vapor deposition (CVD) method, a sputtering method, or an atomic layer epitaxy (ALE) method. In the case where a semiconductor wafer is used for the base substrate, a layer which forms the insulating film can be formed by a method in which the semiconductor wafer is oxidized or nitrided, or the like.

Note that there is no limitation on the order of Steps S4 and S5 in the flow chart of FIG. 1.

Next, the base substrate and the semiconductor wafer are attached to each other (Step S6). In the case where the insulating film is not formed over the base substrate, a surface of the base substrate and a surface of the insulating film over the semiconductor wafer are in contact with each other and pressure is applied thereto, so that the base substrate and the insulating film are attached to each other. In the case where the insulating film is formed over the base substrate, a surface of the insulating film over the base substrate and the surface of the insulating film over the semiconductor wafer are attached to each other. Note that in Step S6, a plurality of semiconductor wafers may be attached to one base substrate.

Next, Step S7 is conducted. Step S7 is a step in which heat treatment is performed to divide the semiconductor wafer at the embrittlement region. In this process, an SOI substrate including the semiconductor film, the insulating film, and the base substrate is formed. The heat treatment in Step S7 can be performed in an RTA apparatus, a heating furnace, or an irradiation apparatus which generates an electromagnetic wave having a frequency band of 300 MHz to 300 GHz (specifically, a microwave irradiation apparatus, or a millimeter wave irradiation apparatus).

Through the above steps, the first manufacturing process of an SOI substrate is completed. That is, k=1 in Step S8.

Next, reprocessing treatment is performed to reuse the semiconductor wafer which is divided in Step S7. In FIG. 1, as the reprocessing treatment, two treatments are described, planarization treatment (Step S9) for planarizing the surface of the semiconductor wafer and heat treatment (Step S11) for reducing crystal defects in the semiconductor wafer.

Since heat treatment in Step S2 is performed on the semiconductor wafer before the first manufacturing process of an SOI substrate is conducted, crystal defects due to a default of the SOI substrate do not exist in the vicinity of the surface of the semiconductor wafer; therefore, heat treatment at high temperature for reducing defects is not necessarily performed as the reprocessing treatment.

Consequently, as illustrated in Step S10, after the planarization treatment in Step S9 is performed, the second manufacturing process of an SOI substrate (S4 to S7) is conducted without the heat treatment in Step S11.

Polishing treatment such as chemical mechanical polishing (CMP), etching treatment such as wet etching, or laser beam irradiation treatment is given for the planarization treatment in Step S9. In Step S9, one or more treatments can be performed, and at least polishing treatment is preferably performed. By performing polishing treatment on the semiconductor wafer, the average surface roughness (Rₐ) of the surface of the semiconductor wafer can be greater than or equal to 0.08 nm and less than or equal to 0.12 nm.

Next, with the use of the semiconductor wafer which is planarized in Step S9, the second manufacturing process of an SOI substrate (S4 to S7) is conducted. The reprocessing treatment (Step S9) and the manufacturing process of an SOI substrate (Steps S4 to S7) are repeatedly conducted until the number of times of the manufacturing process of SOI substrates reaches N, as illustrated in FIG. 1.

When the number of times of performing Steps S4 to S7 reaches N (k=N) in Step S10, after the planarization treatment (Step S9) is performed, heat treatment is performed under a non-oxidizing atmosphere (Step S11).

The heat treatment in Step S11 is heat treatment for eliminating crystal defects (BMDs) due to oxide precipitate in the semiconductor wafer. By repeatedly performing Steps S4 to S9, BMDs are generated inside the semiconductor wafer and a DZ of the semiconductor wafer is gradually reduced. Therefore, when Steps S4 to S9 are repeatedly performed, the vicinity of the surface of the semiconductor wafer cannot be used as a semiconductor film of an SOI substrate because of an increase in crystal defects.

For this reason, in Step S11, heat treatment is performed on the semiconductor wafer at a temperature of higher than or equal to 1100° C. and lower than or equal to 1300° C. under a non-oxidizing atmosphere. This heat treatment is performed under conditions that outward diffusion of oxygen in the semiconductor wafer is performed, and can be performed in a manner similar to Step S2. The description of Step S2 can be referred for the heat treatment in Step S11. Note that conditions of the heat treatment in Step S2 and conditions of the heat treatment in Step S11 are not necessarily the same in the flow chart of FIG. 1. Further, Step S11 is performed a plurality of times; however, conditions of the heat treatments do not need to be the same.

After Step S11 is performed, the process returns to Step S3. Then, the number of times of the manufacturing process of an SOI substrate k is reset to zero. After Steps S4 to S9 are performed N times, the heat treatment in Step S11 is conducted. As long as the semiconductor wafer can be reused, Steps S3 to S11 are repeatedly performed.

In Step S2, the above heat treatment is performed on a new semiconductor wafer, whereby heat treatment at high temperature does not need to be performed on the semiconductor wafer every time the wafer is reused. Thus, the number of times of heat treatment at high temperature is reduced, which can suppress a reduction in a mechanical strength of the semiconductor wafer. Therefore, by Step S2, cost reduction in manufacturing an SOI substrate and improvement in productivity can be achieved.

In addition, by performing heat treatment of Step S2, a semiconductor film of the SOI substrate can be formed using a DZ in which oxygen is reduced more than that in an initial semiconductor wafer. Since generation of BMDs in the semiconductor film is suppressed during a manufacturing process of a semiconductor device such as a transistor using an SOI substrate, a semiconductor device with high reliability can be manufactured.

Note that in order to form a DZ in a surface region of the semiconductor wafer reliably in Step S2, a semiconductor wafer having an oxygen concentration of lower than or equal to 2×10¹⁸ atoms/cm³ is preferably prepared in Step S1. As such a semiconductor wafer, for example, a commercial CZ single crystal silicon wafer is given.

By reducing the oxygen concentration of the semiconductor wafer, generation of crystal defects due to oxygen in the vicinity of the surface of the semiconductor wafer is suppressed; therefore, a DZ can be formed reliably in Step S2 and the DZ can be made thick easily. Reliable formation of the DZ leads to improvement of the yield of the SOI substrate. In addition, to make the DZ thick leads to a reduction in the number of times of heat treatment at high temperature for reprocessing treatment with respect to the number of times of reusing the semiconductor wafer, and shortening of the process time.

Further, by repeatedly performing heat treatment on the semiconductor wafer, BMDs in the semiconductor wafer grow to be crystal defects such as dislocation or stacking fault in some cases. A reduction in the oxygen concentration of the semiconductor wafer can suppress generation of crystal defects due to the BMDs, which leads to an increase in the number of times of use of the semiconductor wafer and improvement in the quality of the semiconductor film of the SOI substrate, and the like.

For these reasons, a semiconductor wafer having an oxygen concentration of lower than or equal to 2×10¹⁸ atoms/cm³ is preferably prepared in Step S1. Further, it is preferable that the oxygen concentration of the semiconductor wafer be lower than or equal to 1.8×10¹⁸ atoms/cm³, more preferably lower than or equal to 1.4×10¹⁸ atoms/cm³. As a semiconductor wafer having an oxygen concentration of lower than or equal to 1.4×10¹⁸ atoms/cm³, for example, an MCZ single crystal silicon wafer is given.

The oxygen concentration of the semiconductor wafer can be measured by secondary ion mass spectrometry (SIMS) or an infrared absorption spectroscopy. In this specification, the oxygen concentration of the semiconductor wafer is measured by the infrared absorption spectroscopy. The infrared absorption spectroscopy is a method by which the oxygen concentration of the whole semiconductor wafer can be measured without destruction. In the case where a single crystal silicon wafer is used, the following formulae (5) and (6) are used to calculate an oxygen concentration O_{conc} using the measured infrared absorption spectrum.

I=I₀exp(−α₁t) (5)

O_{conc}=α₁×K (6)

In the formula (5), I₀ is the transmittance of a background of the infrared absorption spectrum; I is the transmittance of the peak that appears at around 1106 cm⁻¹ (9.1 μm); α₁ is the absorption coefficient at the same peak; and t is the thickness of the single crystal silicon wafer. In the formula (6), K is a constant. Here, as the constant K, 4.81×10¹⁷ [cm²](ASTM-121) which is a value standardized by American Society for Testing Materials (ASTM) is used.

The absorption coefficient α₁ is calculated by the formula (5). When the absorption coefficient α₁ is multiplied by the constant K as shown in the formula (6), the oxygen concentration O_{conc} can be obtained. Note that in the case where a sample used as a reference for removing the influence of the background of the infrared absorption spectrum is air, α₂=α₁−0.4 [cm⁻¹] is substituted for α₁ to obtain the oxygen concentration O_{conc}.

Note that in Step S10, whether or not heat treatment is performed in Step S11 may be determined in accordance with the thickness of a DZ formed in the semiconductor wafer. The thickness of a DZ formed in the semiconductor wafer can be evaluated by measuring crystal defects formed in the semiconductor wafer. A method for measuring crystal defects formed in the semiconductor wafer may be a method for evaluating the crystal defects in the semiconductor wafer without destruction. For example, an infrared light absorption spectroscopy, an infrared light interference method, Raman spectroscopy, a cathode luminescence method, a photoluminescence method, or a microwave photoconductivity decay method is employed. The microwave photoconductivity decay (μ−PCD) method is a method for measuring a lifetime of minority carriers reflecting a state of crystals which are measurement samples using a time change in the reflectivity of a microwave, without destruction.

Note that in the flow chart of FIG. 1, the heat treatment for reprocessing the semiconductor wafer (Step S11) is performed after the manufacturing process of an SOI substrate is performed N times; however, there is no particular limitation on the value of N. For example, the heat treatment can be performed after BMDs of the semiconductor wafer are increased and a DZ of the semiconductor wafer becomes thin. Therefore, the value of N can be determined depending on the oxygen concentration of the semiconductor wafer, the thickness of a DZ formed in the semiconductor wafer, or the like, after heat treatment shown Step S2 or Step S11. Further, the value of N may be different every time Step S11 is conducted. For example, after the manufacturing process of an SOI substrate is performed 6 times, heat treatment in the first Step S11 can be performed, and then after the manufacturing process of an SOI substrate is performed 4 times, heat treatment in the second Step S11 can be performed.

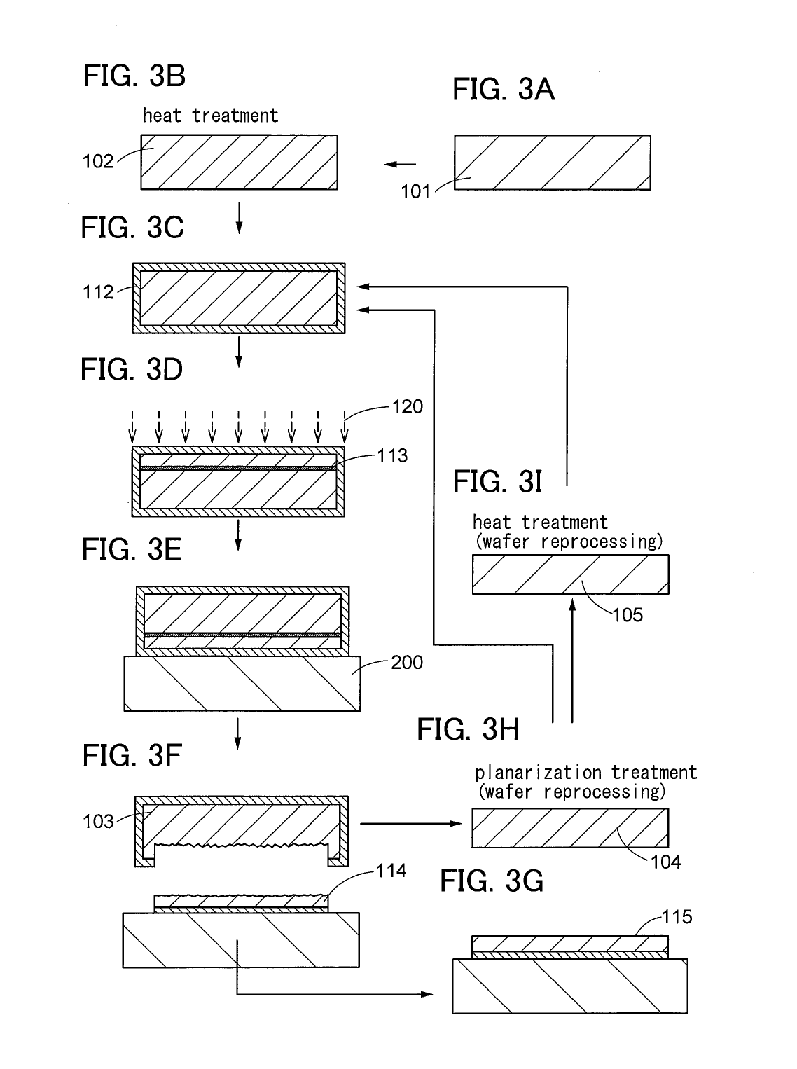

Next, an example of a manufacturing process of an SOI substrate is described using cross-sectional views. The manufacturing example of an SOI substrate is described below with reference to FIG. 1, FIG. 2, and FIG. 3A to 3I.

### <Method for Manufacturing SOI Substrate>

An example of a method for manufacturing an SOI substrate is described with reference to FIGS. 3A to 3I.

FIG. 3A is a cross-sectional view illustrating a step corresponding to Step S1 in FIG. 1. In this manufacturing example, a new single crystal silicon wafer 101 (hereinafter, called a silicon wafer) is used as the bond substrate.

FIG. 3B is a cross-sectional view illustrating a step corresponding to Step S2 in FIG. 1. In this manufacturing example, heat treatment is performed on the silicon wafer at a temperature of higher than or equal to 1100° C. and lower than or equal to 1300° C. under a non-oxidizing atmosphere. Here, the silicon wafer is heated at 1200° C. for 16 hours using a vertical heating furnace. The atmosphere of the heat treatment is an argon atmosphere.

As described with reference to Step S2 in FIG. 1, by performing this heat treatment on a new silicon wafer, a DZ layer (not shown) can be formed in the silicon wafer. FIG. 3B illustrates a silicon wafer 102 in which a DZ layer is formed.

By formation of the DZ layer in the silicon wafer, the silicon wafer can be repeatedly used without heat treatment at high temperature every time reprocessing treatment is conducted. The number of times of reuse without heat treatment at high temperature depends on temperature and time of the heat treatment, the thickness of the DZ layer, conditions of polishing treatment in the reprocessing treatment, or the like; however, when the amount of polishing is lower than or equal to 4 μm, a commercial MCZ single crystal silicon wafer can be used at least 16 times without the heat treatment at high temperature in Step S11 in FIG. 1 by the heat treatment at high temperature in Step S2 under the above conditions. Further, an SOI substrate is manufactured in accordance with the flow chart of FIG. 1, whereby an SOI substrate can be manufactured at least 40 times or more with one silicon wafer (thickness: 0.7 mm).

Furthermore, as described with reference to Step S2 in FIG. 1, impurities in the treatment gas are reduced in heat treatment or the transfer speed of the silicon wafer is controlled when the silicon wafer is taken out from the treatment chamber to the boat carrying-in/out chamber in the unload process after the heat treatment, whereby the average surface roughness of the surface of the silicon wafer 102 can be reduced. Specifically, the average surface roughness of the surface of the semiconductor wafer 102 can be less than or equal to 0.4 nm, preferably less than or equal to 0.2 nm, more preferably less than 0.1 nm.

FIGS. 3C and 3D are cross-sectional views illustrating a step corresponding to Step S4 in FIG. 1. After the heat treatment is finished, an insulating film is formed over the silicon wafer 101 as illustrated in FIG. 3C. Here, the silicon wafer 102 is thermally oxidized to form a silicon oxide film 112. The thermal oxidation treatment may be dry oxidation and is preferably performed under an atmosphere in which a halogen gas or a halogen compound gas is added to an O₂ gas. As such a gas, a kind or plural kinds of gases selected from HCl, HF, NF₃, HBr, Cl₂, ClF₃, BCl₃, F₂, Br₂, and the like can be used.

For example, heat treatment is performed at a temperature of higher than or equal to 900° C. and lower than or equal to 1100° C. under an atmosphere containing HCl at a concentration of higher than or equal to 0.5 vol. % and lower than or equal to 10 vol. % with respect to O₂, so that a silicon oxide film 112 containing chlorine can be formed. Here, the process time is greater than or equal to 0.1 hours and less than or equal to 6 hours. Further, the thickness of the silicon oxide film 112 is greater than or equal to 50 nm and less than or equal to 200 nm. Here, the heat treatment is performed on the silicon wafer 102 at 950° C. under an O₂ gas atmosphere containing HCl at 3 vol. %, whereby the silicon oxide film 112 (thermal oxide film) is formed to a thickness of 100 nm.

Improvement in the planarity of the surface of the silicon wafer 102 illustrated in FIG. 3B can lead to improvement in the planarity of the silicon oxide film 112 illustrated in FIG. 3C. Specifically, the planarity of the silicon oxide film 112 can be less than or equal to 0.4 nm, preferably less than or equal to 0.2 nm, more preferably less than 0.1 nm.

Next, as illustrated in FIG. 3D, irradiation with ions 120 is performed to form an embrittlement region 113 in the silicon wafer 102. An ion implantation apparatus or an ion doping apparatus can be used for the irradiation with the ions 120. In an ion implantation apparatus, a source gas is excited to generate ion species, the generated ion species are mass-separated, and an object to be processed is irradiated with the ion species having a predetermined mass. In an ion doping apparatus, a process gas is excited to generate ion species, the generated ion species are not mass-separated, and the object to be processed is irradiated with the generated ion species. Note that in the ion doping apparatus provided with a mass separator, ion irradiation with mass separation can also be performed as in the ion implantation apparatus.

Since the ions 120 are accelerated by an electric field and have kinetic energy, the embrittlement region 113 can be formed in a region at a predetermined depth from a surface of the silicon wafer 102 by the irradiation with the ions 120. The depth at which the embrittlement region 113 is formed can be controlled by acceleration energy of the ions 120 or the incidence angle thereof, and the embrittlement region 113 is formed in a region at the same depth or substantially the same depth as the average penetration depth of the ions 120. In addition, the depth at which the embrittlement region 113 is formed determines the thickness of a semiconductor film to be separated from the silicon wafer 102. The depth at which the embrittlement region 113 is formed is greater than or equal to 30 nm and less than or equal to 1 μm from the surface of the silicon wafer 102, and is preferably greater than or equal to 50 nm and less than or equal to 300 nm.

A typical source gas of the ions 120 is a H₂ gas. As well as a H₂ gas, a rare gas such as helium or argon, a halogen gas typified by a fluorine gas or a chlorine gas, and a halogen compound gas such as a fluorine compound gas (e.g., BF₃) can be used. One or more kinds of gases can be used as the source gas.

The irradiation with the ions 120 can be performed a plurality of times to form the embrittlement region 113. In this case, different source gases may be used for ion irradiation or the same source gas may be used for the ion irradiation. For example, ion irradiation can be performed using a gas containing hydrogen as a source gas after ion irradiation is performed using a rare gas as a source gas. Alternatively, ion irradiation can be performed first using a halogen gas or a halogen compound gas, and then, ion irradiation can be performed using the gas containing hydrogen.

Here, an ion doping apparatus is used for the formation of the embrittlement region 113 and a H₂ gas is used as the source gas of the ions 120. For example, the silicon wafer 102 is irradiated with hydrogen ions through the silicon oxide film 112 with an acceleration voltage of 50 kV at a dose of 2.7×10¹⁶ ions/cm².

FIG. 3E is a cross-sectional view illustrating a step corresponding to Step S6 in FIG. 1. Next, a base substrate and the silicon wafer 102 are attached to each other as illustrated in FIG. 3E. Here, a glass substrate 200 is used as the base substrate. Instead of the glass substrate 200, a single crystal silicon wafer may be used similarly to the silicon wafer 101. Further, an insulating film may be formed over the glass substrate 200 by a PECVD method or the like as illustrated with reference to Step S5 in FIG. 1.

Before the attachment, the silicon wafer 102 and the glass substrate 200 are subjected to cleaning treatment to clean the surfaces to be attached. When the silicon wafer 102 and the glass substrate 200 are pressed with the surface of the glass substrate 200 and the surface of the silicon oxide film 112 being in contact with each other, the glass substrate 200 and the silicon oxide film 112 are bonded to each other, so that the glass substrate 200 and the silicon wafer 102 are attached to each other.

In the case where the average surface roughness (Rₐ) of each of the glass substrate 200 and the silicon wafer 102 is greater than 0.4 nm in attaching the glass substrate 200 and the silicon wafer 102 to each other, an attachment defect such as an air void may be caused at the attachment interface between the glass substrate 200 and the silicon wafer 102. Further, the present inventors have confirmed that in the case where the average surface roughness (Rₐ) of each of the glass substrate 200 and the silicon wafer 102 is greater than or equal to 0.8 nm, the glass substrate 200 and the silicon wafer 102 cannot be spontaneously bonded to each other. Therefore, the average surface roughness of the glass substrate 200 is also less than 0.8 nm, preferably less than or equal to 0.4 nm, more preferably 0.2 nm.

In one embodiment of the present invention, the average surface roughness of the oxide film formed by heat treatment on the silicon wafer 102 can be less than or equal to 0.4 nm, preferably less than or equal to 0.2 nm, more preferably less than 0.1 nm. Therefore, the average surface roughness of the silicon oxide film 112 formed on the silicon wafer 102 can be less than or equal to 0.4 nm, preferably less than or equal to 0.2 nm, more preferably less than 0.1 nm. As a result, an attachment defect such as an air void can be reduced in attaching the silicon wafer 102 and the glass substrate 200 to each other.

Then, the glass substrate 200 and the silicon wafer 102 may be subjected to heat treatment to increase the attachment strength. The heat treatment temperature needs to be a temperature at which separation does not proceed at the embrittlement region 113 and may be higher than or equal to 200° C. and lower than or equal to 300° C.

FIG. 3F is a cross-sectional view illustrating a step corresponding to Step S7 in FIG. 1. As illustrated in FIG. 3F, the silicon wafer 102 is divided at the embrittlement region 113 and a single crystal silicon film 114 is formed from the silicon wafer 102. Here, heat treatment is performed on the silicon wafer 102 which is fixed to the glass substrate 200 in a heating furnace. The heat treatment temperature is preferably higher than or equal to 400° C. and is limited by an allowable temperature limit of the glass substrate 200 (base substrate) or the like. A heating furnace or an RTA apparatus can be used for this heat treatment. The heat treatment is performed to generate a crack in the embrittlement region 113 and separate the silicon wafer 103 and the glass substrate 200 into a silicon wafer 103 and an SOI substrate including the single crystal silicon film 114, the silicon oxide film 112, and the glass substrate 200. The silicon wafer 103 is a wafer before the reprocessing treatment.

Here, a series of heat treatments, which serves as treatment for increasing the attachment strength between the glass substrate 200 and the silicon oxide film 112 and treatment for dividing the silicon wafer 102, is performed in a heating furnace. Specifically, the silicon wafer 102 fixed to the glass substrate 200 is heated at 200° C. for 2 hours in the heating furnace, and then the temperature is raised to 600° C. and heating is performed for 2 hours.

Next, as illustrated in FIG. 3G, the single crystal silicon film 114 of the SOI substrate is planarized to form a single crystal silicon film 115. Here, since the base substrate of the SOI substrate is the glass substrate 200 having low heat resistance, it is difficult to perform planarization by heat treatment; therefore, the single crystal silicon film 114 is irradiated with a laser beam as planarization treatment. Note that the single crystal silicon film 114 may be etched as necessary before the laser beam irradiation treatment is performed. This etching treatment can remove the embrittlement region 113 left on a surface of the single crystal silicon film 114.

Examples of a laser that is used for the laser beam irradiation treatment include an excimer laser such as a XeCl laser or a KrF laser and a gas laser such as an Ar laser or a Kr laser. Other examples that can be used are solid-state lasers such as a YAG laser, a YVO₄ laser, a YLF laser, a YAlO₃ laser, a GdVO₄ laser, a KGW laser, a KYW laser, and a Y₂O₃ laser. As laser light, the fundamental wave, a harmonic (such as a second harmonic, a third harmonic, or a fourth harmonic) of any of these lasers can be used. Note that some of these solid-state lasers can be either a continuous wave laser or a quasi-continuous wave laser even when using the same laser medium.

When the laser beam irradiation is performed, the single crystal silicon film 114 absorbs a laser beam to be melted. When energy of the laser beam is not supplied to a melted region, the temperature is rapidly decreased and the melted region is solidified. As a result, the single crystal silicon film 115 whose planarity is improved can be formed. Further, since crystals of the single crystal silicon film 114 can be rearranged by the melting, dangling bonds and the like in the single crystal silicon film 115 can be reduced. As described above, the single crystal silicon film 115 whose planarity and crystallinity are improved is formed by the laser beam irradiation treatment.

However, BMDs in the single crystal silicon film 115 are hardly eliminated by the laser beam irradiation treatment. Therefore, in the case where a base substrate with an allowable temperature limit of lower than or equal to 1100° C. is used, it is significantly effective to perform heat treatment at high temperature on the semiconductor wafer before an SOI substrate is manufactured in improvement of the quality of the SOI substrate. This is because when the allowable temperature limit of the base substrate is lower than or equal to 1100° C., heat treatment cannot be performed at a temperature at which BMDs can be effectively eliminated from the semiconductor layer over the base substrate. In addition, there is no proper method which can be substituted for the heat treatment. For this reason, in the case where a base substrate with low heat resistance is used, it is required that the semiconductor layer which has as less oxide precipitate as possible is formed over the base substrate. Therefore, it is significantly effective to form a semiconductor film from DZs whose oxygen concentration is reduced in improvement of the quality of the SOI substrate formed using the base substrate with low heat resistance. According to this embodiment, even when a base substrate whose allowable temperature limit is lower than or equal to 700° C. such as a glass substrate is used, an SOI substrate with high quality can be manufactured.

Further, a step of reducing the thickness of the single crystal silicon film 115 of the SOI substrate in FIG. 3G may be conducted. Here, since the glass substrate 200 is used for the base substrate, dry etching and/or wet etching may be performed as treatment of reducing the thickness of the single crystal silicon film 115. In the case where a semiconductor wafer is used for the base substrate, known treatment of reducing the thickness in which polishing treatment, thermal oxidation treatment, and etching treatment are combined may be performed.

Reprocessing treatment of the silicon wafer 101 from which the single crystal silicon film 114 is separated is described below. The reprocessing treatment includes planarization treatment (see FIG. 3H) and heat treatment at a temperature of higher than or equal to 1100° C. under a non-oxidizing atmosphere (see FIG. 3I). As illustrated with reference to Step 9 in FIG. 1, the planarization treatment in FIG. 3H is performed every time the bond substrate is reprocessed. FIG. 3H shows a reprocessed silicon wafer 104 which is reprocessed by the planarization treatment. The reprocessed silicon wafer 104 is reused as the bond substrate (silicon wafer 102) in FIG. 3C.

Further, as illustrated with reference to Step 11 in FIG. 1, heat treatment in FIG. 3I is intermittently performed and is performed on the reprocessed silicon wafer 104 after planarization treatment in FIG. 3H, as reprocessing treatment after a manufacturing process of an SOI substrate (FIG. 3C to FIG. 3F) is performed plural times. A reprocessed silicon wafer 105 after the heat treatment is reused as the bond substrate (silicon wafer 102) in FIG. 3C.

The reprocessed silicon wafer 104 can be manufactured by the planarization treatment in FIG. 3H, for example, in the following manner. First, the silicon oxide film 112 left on the silicon wafer 103 is removed by wet etching using buffered hydrofluoric acid. Next, a separation surface of the single crystal silicon film 114 is polished with a CMP apparatus. Further, before the polishing using the CMP apparatus, etching may be performed using a Dash etchant, a Sato etchant, a mixed etchant of hydrofluoric acid and hydrogen peroxide water, or the like. Through this etching, a projected portion around the silicon wafer 103 (a portion which has not been attached to the glass substrate 200) can be removed, so that the amount of polishing with the CMP apparatus can be reduced.

Alternatively, in order to manufacture the reprocessed silicon wafer 105 by the heat treatment in FIG. 3I, for example, the reprocessed silicon wafer 104 may be heated at 1200° C. for 1 hour or longer under an argon atmosphere using a heating furnace, similarly to the heat treatment in FIG. 3B.

Through the above steps, an SOI substrate can be manufactured and the semiconductor wafer after the division can be reprocessed.

A semiconductor wafer having an oxygen concentration of lower than or equal to 2×10¹⁸ atoms/cm³ is subjected to heat treatment, whereby a DZ can be formed in the semiconductor wafer. Formation of a DZ in the semiconductor wafer makes it possible to perform Steps S4 to S9 illustrated in FIG. 1 (manufacturing process of an SOI substrate) plural times. Further, heat treatment at high temperature does not need to be performed on the semiconductor wafer every time the semiconductor wafer is reused. Thus, the number of times of heat treatment at high temperature is reduced, which can suppress a reduction in a mechanical strength of the semiconductor wafer. Therefore, by Step S2, cost reduction in manufacturing an SOI substrate and improvement in productivity can be achieved.

A reduction in the concentration of impurities contained in the treatment gas used for heat treatment makes it possible to suppress formation of a non-uniform natural oxide film through the reaction between impurities and the semiconductor wafer in the heat treatment. Therefore, the average surface roughness of the semiconductor wafer can be reduced.

The semiconductor wafer in which the average surface roughness is reduced and the base substrate are attached to each other, whereby an attachment defect such as an air void at the interface between the semiconductor wafer and the base substrate can be prevented.

Further, with the use of a vertical heating furnace by which a plurality of semiconductor wafers can be treated, a dummy substrate is not necessary or the number of dummy substrates can be reduced. This makes it possible to increase the number of substrates which can be treated at a time.

As described above, productivity of an SOI substrate can be increased.

### Example 1

Heat treatment was performed on new CZ single crystal silicon wafers (hereinafter called CZ wafers). A result obtained by examining the planarity of a surface of the CZ wafers after the heat treatment is described in this example.

First, three new CZ wafers (manufactured by SUMCO CORPORATION, 5 square inches, p-type, and plane orientation (100)) were prepared.

Next, the three CZ wafers were cleaned. Specifically, cleaning was performed using sequentially cleaning solutions such as a sulfuric acid/hydrogen peroxide mixture (SPM), a hydrochloric acid/hydrogen peroxide mixture (HPM), and a hydrofluoric acid/hydrogen peroxide mixture (FPM).

Next, with a vertical heating furnace as illustrated in FIG. 2, heat treatment was performed on the three CZ wafers. A boat in the heating furnace used in this example can carry 130 wafers.

As Condition 1, two of the three CZ wafers, which were set in the boat, were transferred to a treatment chamber, and heat treatment at 1200° C. was performed under an argon gas atmosphere containing water at 300 ppb and for 16 hours. In the two CZ wafers under Condition 1, the CZ wafer set in the 117-th holder from the bottom of the boat is described as Wafer A1 and the CZ wafer set in the 17-th holder from the bottom of the boat is described as Wafer A2.

Further, as Condition 2, the third CZ wafer, which was set in the boat, was transferred to the treatment chamber, and heat treatment was performed under an argon atmosphere containing a nitrogen gas at 1% at 1200° C. and for 2 hours. Under Condition 2, the CZ wafer set in the 119-th holder from the bottom of the boat is described as Wafer B1.

Next, the planarity of each of the CZ wafers was measured. The planarity of each of the CZ wafers was measured by an atomic force microscope (hereinafter referred to as AFM).

The average surface roughness (Rₐ) of each of Wafer A1 and Wafer A2 was measured at 8 points. Table 1 shows the average surface roughness (Rₐ) at each point of Wafer A1 and Table 2 shows the average surface roughness (Rₐ) at each point of Wafer A2. Note that the average surface roughness (Rₐ) at each point was measured with a measurement area of 1 μm×1 μm.

TABLE 1

| | X[mm] | Y[mm] | Ra [nm] |
|---|---|---|---|
| 1 | 57 | 57 | 0.300 |
| 2 | 57 | 44 | 0.225 |
| 3 | 57 | 5 | 0.269 |
| 4 | 2.5 | 5 | 0.0343 |
| 5 | −57 | 5 | 0.307 |
| 6 | −57 | 44 | 0.192 |
| 7 | −57 | 57 | 0.289 |
| 8 | 2.5 | 57 | 0.334 |

TABLE 2

| | X[mm] | Y[mm] | Ra [nm] |
|---|---|---|---|
| 1 | 57 | 57 | 0.0412 |
| 2 | 57 | 44 | 0.0308 |
| 3 | 57 | 5 | 0.0312 |
| 4 | 2.5 | 5 | 0.0336 |
| 5 | −57 | 5 | 0.0408 |
| 6 | −57 | 44 | 0.03 |
| 7 | −57 | 57 | 0.0403 |
| 8 | 2.5 | 57 | 0.0305 |

The average surface roughness of each of Wafer B1 and Wafer B2 was measured at 8 points. Table 3 shows the average surface roughness (Rₐ) at each point of Wafer B1. Note that the average surface roughness (Rₐ) at each point was measured with a measurement area of 1 μm×1 μm.

TABLE 3

| | X[mm] | Y[mm] | Ra [nm] |
|---|---|---|---|
| 1 | 57 | 57 | 0.264 |
| 2 | 57 | 44 | 0.0935 |
| 3 | 57 | 5 | 0.532 |
| 4 | 2.5 | 5 | 0.572 |
| 5 | −57 | 5 | 5.07 |
| 6 | −57 | 44 | 2.16 |
| 7 | −57 | 57 | 0.215 |
| 8 | 2.5 | 57 | 3.44 |

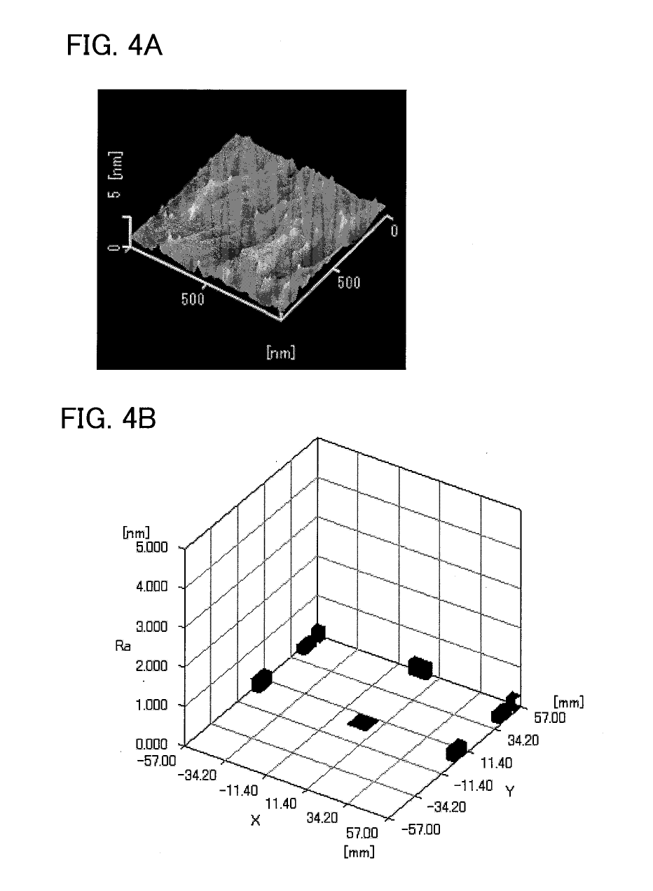

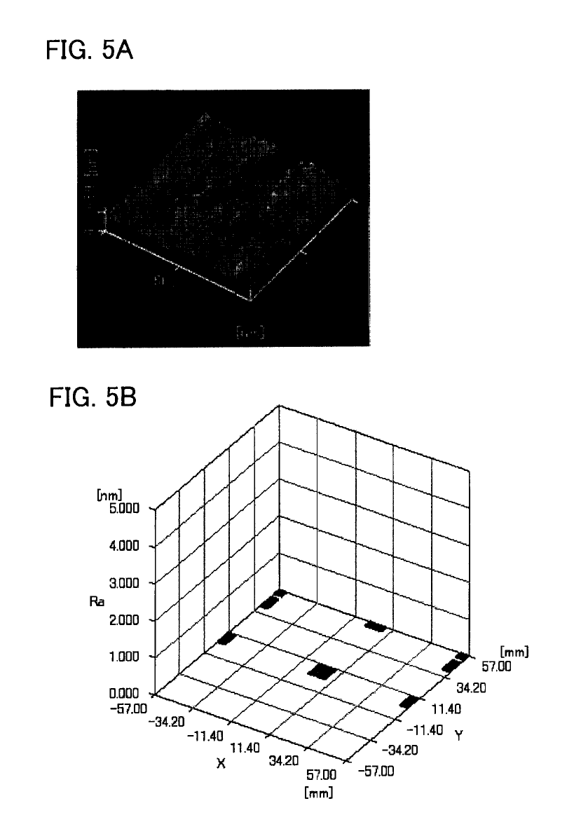

FIG. 4A shows an observation image of Wafer A1 obtained with the AFM and FIG. 4B is a graph showing the average surface roughness (Rₐ) at each point of Wafer A1. Further, FIG. 5A shows an observation image of Wafer A2 obtained with the AFM and FIG. 5B is a graph showing the average surface roughness (Rₐ) at each point of Wafer A2.

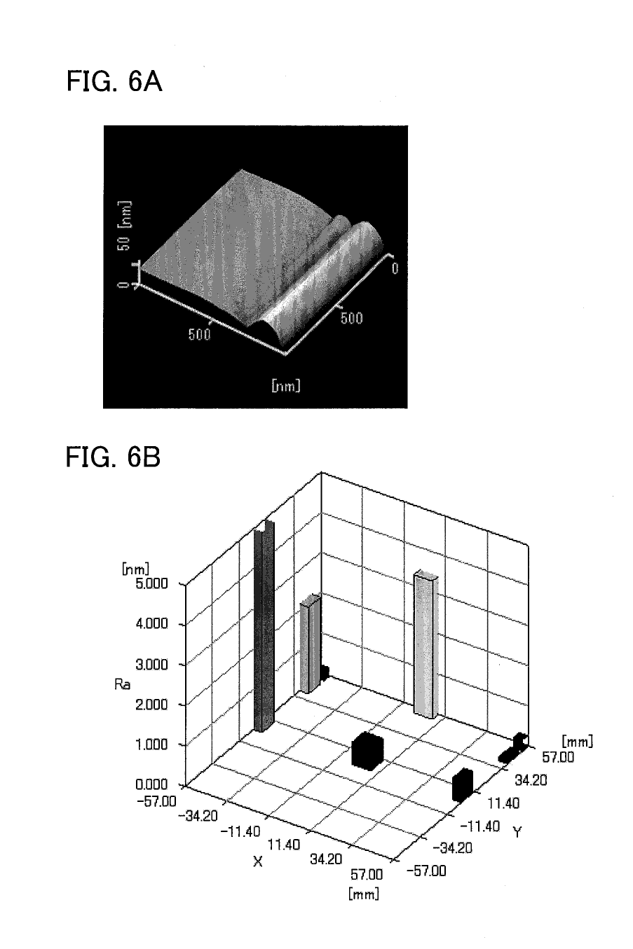

FIG. 6A shows an observation image of Wafer B1 obtained with the AFM and FIG. 6B is a graph showing the average surface roughness (Rₐ) at each point of Wafer B1. Note that the measurement area at each point is 1 μm×1 μm.

Table 3 and FIGS. 6A and 6B show the average surface roughness (Rₐ) of Wafer B1 on which the heat treatment has been performed under the argon atmosphere containing the nitrogen gas at 1% is 2 nm to 5 nm in the peripheral portion of the wafer and approximately 0.5 nm in the central portion of the wafer. In contrast, Table 1, Table 2, FIGS. 4A and 4B, and FIGS. 5A and 5B show the average surface roughness (Rₐ) of Wafer A1 on which the heat treatment was performed under the argon atmosphere containing water at 300 ppb is 0.2 nm to 0.3 nm in the peripheral portion of the wafer and approximately 0.03 nm in the central portion of the wafer. Further, it was confirmed that the average surface roughness (Rₐ) of Wafer A2 is 0.03 nm to 0.04 nm in the peripheral portion and the central portion of the wafer.

Consequently, it was confirmed that a reduction in the concentration of impurities contained in the non-oxidizing atmosphere makes it possible to reduce the average surface roughness of the surface of the semiconductor wafer and to improve the planarity of the semiconductor wafer.

### Example 2

Heat treatment was performed on new CZ wafers. A result obtained by further examining the planarity of a surface of the CZ wafers after the heat treatment is described in this example.

First, two new CZ wafers (manufactured by SUMCO CORPORATION, 5 square inches, p-type, and plane orientation (100)) were prepared.

Next, the two CZ wafers were cleaned. Specifically, cleaning was performed using sequentially cleaning solutions such as a sulfuric acid/hydrogen peroxide mixture (SPM), a hydrochloric acid/hydrogen peroxide mixture (HPM), and a hydrofluoric acid/hydrogen peroxide mixture (FPM).

Next, with a vertical heating furnace as illustrated in FIG. 2, heat treatment was performed on the two CZ wafers. A boat in the heating furnace used in this example can carry 130 wafers.

The two CZ wafers, which were set in the boat, were transferred to a treatment chamber, and heat treatment at 1200° C. was performed under an argon gas atmosphere containing water at 1.2 ppb and for 16 hours. In the two CZ wafers, the CZ wafer set in the 119-th holder from the bottom of the boat is described as Wafer C1 and the CZ wafer set in the 19-th holder from the bottom of the boat is described as Wafer C2.

Next, the planarity of each of the CZ wafers was measured. The planarity of each of the CZ wafers was measured by the AFM.

The average surface roughness (Rₐ) of each of Wafer C1 and Wafer C2 was measured at 8 points. Table 4 shows the average surface roughness (Rₐ) at each point of Wafer C1 and Table 5 shows the average surface roughness (Rₐ) at each point of Wafer C2. Note that the average surface roughness (Rₐ) at each point was measured with a measurement area of 1 μm×1 μm.

TABLE 4

| | X[mm] | Y[mm] | Ra [nm] |
|---|---|---|---|
| 1 | 57 | 57 | 0.05 |
| 2 | 57 | 44 | 0.03 |
| 3 | 57 | 5 | 0.04 |
| 4 | 2.5 | 5 | 0.03 |
| 5 | −57 | 5 | 0.06 |
| 6 | −57 | 44 | 0.03 |
| 7 | −57 | 57 | 0.07 |
| 8 | 2.5 | 57 | 0.06 |

TABLE 5

| | X[mm] | Y[mm] | Ra [nm] |
|---|---|---|---|
| 1 | 57 | 57 | 0.06 |
| 2 | 57 | 44 | 0.04 |
| 3 | 57 | 5 | 0.04 |
| 4 | 2.5 | 5 | 0.03 |
| 5 | −57 | 5 | 0.04 |
| 6 | −57 | 44 | 0.04 |
| 7 | −57 | 57 | 0.03 |
| 8 | 2.5 | 57 | 0.06 |

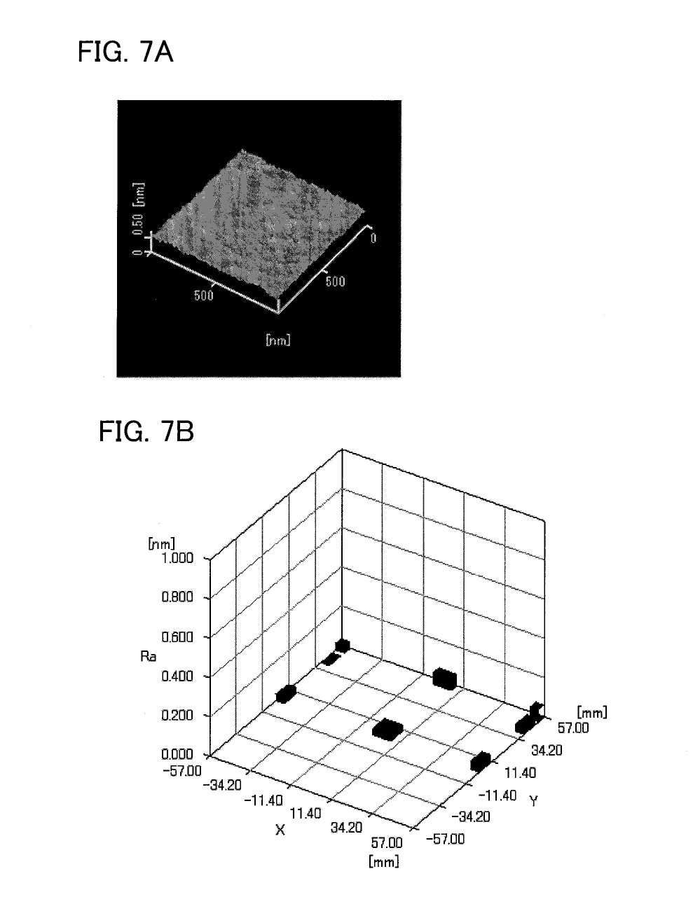

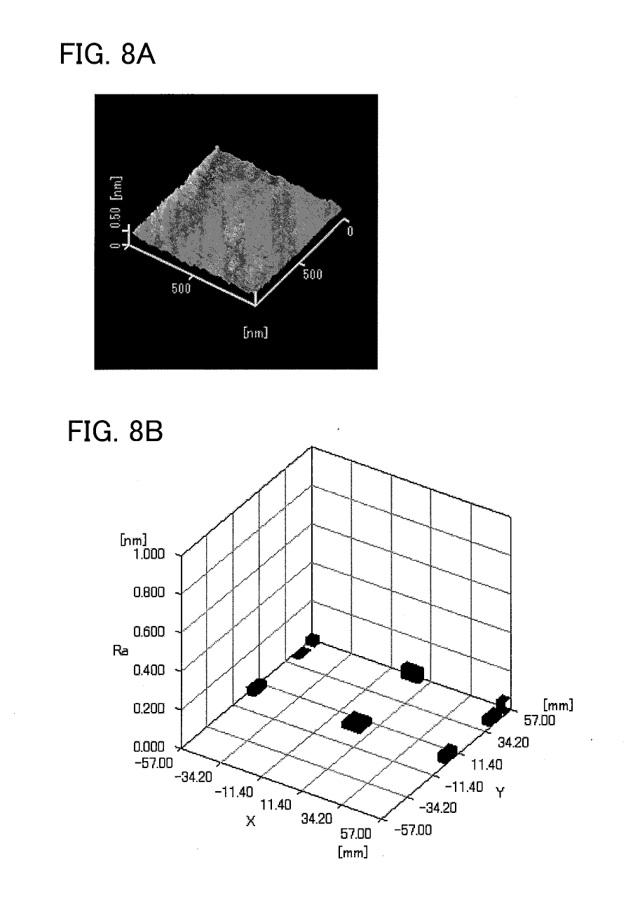

FIG. 7A shows an observation image of Wafer C1 obtained with the AFM and FIG. 7B is a graph showing the average surface roughness (Rₐ) at each point of Wafer C1. Further, FIG. 8A shows an observation image of Wafer C2 obtained with the AFM and FIG. 8B is a graph showing the average surface roughness (Rₐ) at each point of Wafer C2.

Table 4, Table 5, FIGS. 7A and 7B, and FIGS. 8A and 8B show the average surface roughness (Rₐ) of Wafer C1 on which the heat treatment was performed under the argon atmosphere containing water at 1.2 ppb is 0.03 nm to 0.07 nm in the entire wafer and the average surface roughness (Rₐ) of Wafer C2 is 0.03 nm to 0.06 nm in the entire wafer.

Consequently, it was confirmed that an extreme reduction in the concentration of impurities contained in the non-oxidizing atmosphere makes it possible to reduce the average surface roughness of the semiconductor wafer and to improve the planarity of the semiconductor wafer regardless of a position of the semiconductor wafer in the boat in the vertical heating furnace.

This application is based on Japanese Patent Application serial no. 2011-161320 filed with Japan Patent Office on Jul. 22, 2011, the entire contents of which are hereby incorporated by reference.

What is claimed is:

1. A method for manufacturing an SOI substrate, comprising:
a first step of forming a second semiconductor wafer by performing a first heat treatment on a first semiconductor wafer at a temperature of higher than or equal to 1100° C. and lower than or equal to 1300° C. under a non-oxidizing atmosphere containing water at a concentration of higher than or equal to 0.1 ppb and lower than or equal to 300 ppb;
a second step of forming an insulating film on a surface of the second semiconductor wafer and then irradiating the second semiconductor wafer with accelerated ions through the insulating film, to form an embrittlement region in the second semiconductor wafer;
a third step of attaching the second semiconductor wafer and a base substrate to each other with the insulating film interposed therebetween; and
a fourth step of dividing the second semiconductor wafer at the embrittlement region by performing a second heat treatment, to form a semiconductor film fixed to the base substrate with the insulating film interposed therebetween and a third semiconductor wafer from which the semiconductor film has been separated.

2. The method for manufacturing an SOI substrate according to claim 1,
wherein the non-oxidizing atmosphere is a rare gas atmosphere, a hydrogen gas atmosphere, or a mixed atmosphere of a rare gas and a hydrogen gas.

3. The method for manufacturing an SOI substrate according to claim 1,
further comprising a fifth step of planarizing a surface of the third semiconductor wafer, to form a fourth semiconductor wafer.

4. The method for manufacturing an SOI substrate according to claim 3,
further comprising a sixth step of performing the steps from the second step to the fifth step at least once by using the fourth semiconductor wafer as the second semiconductor wafer.

5. A method for manufacturing an SOI substrate, comprising:
a first step of forming a second semiconductor wafer by performing a first heat treatment on a first semiconductor wafer at a temperature of higher than or equal to 1100° C. and lower than or equal to 1300° C. under a non-oxidizing atmosphere and performing an unload process at a transfer speed of the second semiconductor wafer of higher than or equal to 50 mm/min and lower than or equal to 500 mm/min in taking out the second semiconductor wafer from a furnace after a temperature at the furnace where the first heat treatment has been performed is lowered to higher than or equal to 400° C. and lower than or equal to 700° C.;
a second step of forming an insulating film on a surface of the second semiconductor wafer and then irradiating the second semiconductor wafer with accelerated ions through the insulating film, to form an embrittlement region in the second semiconductor wafer;
a third step of attaching the second semiconductor wafer and a base substrate to each other with the insulating film interposed therebetween; and
a fourth step of dividing the second semiconductor wafer at the embrittlement region by performing a second heat treatment, to form a semiconductor film fixed to the base substrate with the insulating film interposed therebetween and a third semiconductor wafer from which the semiconductor film has been separated.

6. The method for manufacturing an SOI substrate according to claim 5,
wherein the non-oxidizing atmosphere contains water at a concentration of higher than or equal to 0.1 ppb and lower than or equal to 300 ppb.

7. The method for manufacturing an SOI substrate according to claim 5,
wherein the non-oxidizing atmosphere is a rare gas atmosphere, a hydrogen gas atmosphere, or a mixed atmosphere of a rare gas and a hydrogen gas.

8. The method for manufacturing an SOI substrate according to claim 5,
further comprising a fifth step of planarizing a surface of the third semiconductor wafer, to form a fourth semiconductor wafer.

9. The method for manufacturing an SOI substrate according to claim 8,
further comprising a sixth step of performing the steps from the second step to the fifth step at least once by using the fourth semiconductor wafer as the second semiconductor wafer.

10. A method for manufacturing SOI substrates, comprising:
a first step of forming a second semiconductor wafer by performing a first heat treatment on a first semiconductor wafer at a temperature of higher than or equal to 1100° C. and lower than or equal to 1300° C. under a first non-oxidizing atmosphere and performing an unload process at a transfer speed of the second semiconductor wafer of higher than or equal to 50 mm/min and lower than or equal to 500 mm/min in taking out the second semiconductor wafer from a furnace after a temperature at the furnace where the first heat treatment has been performed is lowered to higher than or equal to 400° C. and lower than or equal to 700° C.;
a second step of forming an insulating film on a surface of the second semiconductor wafer and then irradiating the second semiconductor wafer with accelerated ions through the insulating film, to form an embrittlement region in the second semiconductor wafer;
a third step of attaching the second semiconductor wafer and a base substrate to each other with the insulating film interposed therebetween; a fourth step of dividing the second semiconductor wafer at the embrittlement region by performing a second heat treatment, to form a semiconductor film fixed to the base substrate with the insulating film interposed therebetween and a third semiconductor wafer from which the semiconductor film has been separated;
a fifth step of planarizing a surface of the third semiconductor wafer, to form a fourth semiconductor wafer;
a sixth step of performing the steps from the second step to the fifth step at least once by using the fourth semiconductor wafer as the second semiconductor wafer;
a seventh step of forming a fifth semiconductor wafer by performing a third heat treatment on the fourth semiconductor wafer at a temperature of higher than or equal to 1100° C. and lower than or equal to 1300° C. under a second non-oxidizing atmosphere and performing an unload process at a transfer speed of the fifth semiconductor wafer of higher than or equal to 50 mm/min and lower than or equal to 500 mm/min in taking out the fifth semiconductor wafer from the furnace after a temperature at the furnace where the third heat treatment has been performed is lowered to higher than or equal to 400° C. and lower than or equal to 700° C.; and
an eighth step of performing the steps from the second step to the fifth step at least once by using the fifth semiconductor wafer as the second semiconductor wafer.

11. The method for manufacturing SOI substrates according to claim 10,
wherein the first non-oxidizing atmosphere and the second non-oxidizing atmosphere contain water at a concentration of higher than or equal to 0.1 ppb and lower than or equal to 300 ppb.

12. The method for manufacturing SOI substrates according to claim 10,
wherein the first non-oxidizing atmosphere is a rare gas atmosphere, a hydrogen gas atmosphere, or a mixed atmosphere of a rare gas and a hydrogen gas.

13. The method for manufacturing SOI substrates according to claim 10,
wherein the second non-oxidizing atmosphere is a rare gas atmosphere, a hydrogen gas atmosphere, or a mixed atmosphere of a rare gas and a hydrogen gas.
